(19) United States
(12) Patent Application Publication
(10) Pub. No.: US 2026/0344415 A1
(43) Pub. Date: Oct. 29, 2026

(54) SEMICONDUCTOR STRUCTURE AND A METHOD FOR MANUFACTURING THE SAME

(71) Applicant: MACRONIX INTERNATIONAL CO., LTD., Hsinchu (TW)

(72) Inventors: Erh-Kun LAI, Taichung County (TW); Hsiang-Lan LUNG, Kaohsiung City (TW)

(21) Appl. No.: 19/189,328

(22) Filed: Apr. 25, 2025

(51) Int. Cl. H10W 20/40; H01F 27/28; H01F 38/14; H01F 41/04; H10D 1/00; H10D 1/20; H10W 20/42

(52) U.S. Cl. CPC H10W 20/497; H01F 27/2804; H01F 38/14; H01F 41/041; H10D 1/01; H10D 1/20; H10W 20/42

(57) ABSTRACT

A semiconductor structure is provided. The semiconductor structure includes a 3D transformer structure. The 3D transformer structure includes a plurality of conductive layers arranged in parallel. The conductive layers have U-shaped configurations. The conductive layers includes at least one conductive layer forming a primary circuit of the 3D transformer structure and at least one conductive layer forming a secondary circuit of the 3D transformer structure, and the at least one conductive layer of the primary circuit and the at least one conductive layer of the secondary circuit is electrically isolated from each other.

### TECHNICAL FIELD

This disclosure relates to a semiconductor structure and a method for manufacturing the same. More particularly, this disclosure relates to a semiconductor structure including a 3D transformer structure and a method for manufacturing the same.

### BACKGROUND

The realization of fully integrated systems with on-chip components is critical for reducing the production costs and the overall device sizes in various emerging technical fields, such as 5G wireless communication. In this regard, the integration of many passive devices like inductors, capacitors, and transformers is important, since they serve as the fundamental building blocks of many integrated circuits and their performance largely affects the overall circuit performances. Among others, on-chip transformers are used in various circuits, including low noise amplifiers (LNAs), voltage-controlled oscillators (VCO), impedance matching circuits, DC isolation circuits, power transfer circuits, and in baluns for power conversion between single-ended and differential-ended circuits, and so on. In most cases, on-chip transformers are formed by only the last one or two metal layers for reducing the transformer resistance through larger metal thickness. However, such an on-chip transformer typically occupies a large area on the chip.

### SUMMARY

In this disclosure, a semiconductor structure with a 3D transformer structure occupying a small area and a method for manufacturing the same are provided.

A semiconductor structure according to the disclosure comprises a 3D transformer structure. The 3D transformer structure comprises a plurality of conductive layers arranged in parallel. The conductive layers have U-shaped configurations. The conductive layers comprise at least one conductive layer forming a primary circuit of the 3D transformer structure and at least one conductive layer forming a secondary circuit of the 3D transformer structure, and the at least one conductive layer of the primary circuit and the at least one conductive layer of the secondary circuit is electrically isolated from each other.

A method for manufacturing a semiconductor structure according to the disclosure comprises forming a 3D transformer structure. Forming the 3D transformer structure comprises forming a plurality of conductive layers arranged in parallel. The conductive layers have U-shaped configurations. The conductive layers comprise at least one conductive layer forming a primary circuit of the 3D transformer structure and at least one conductive layer forming a secondary circuit of the 3D transformer structure, and the at least one conductive layer of the primary circuit and the at least one conductive layer of the secondary circuit is electrically isolated from each other.

### BRIEF DESCRIPTION OF THE DRAWINGS

FIGS. 1A-1D illustrate an exemplary semiconductor structure according to the disclosure.

FIGS. 2A-2B illustrate an exemplary semiconductor structure according to the disclosure.

FIG. 3 illustrates an exemplary semiconductor structure according to the disclosure.

FIGS. 4A-4D illustrate an exemplary semiconductor structure according to the disclosure.

FIGS. 5A-5B illustrate an exemplary semiconductor structure according to the disclosure.

FIG. 6 illustrates an exemplary semiconductor structure according to the disclosure.

FIGS. 7 to 15A-15C illustrate various stages of an exemplary method for manufacturing a semiconductor structure according to the disclosure.

FIGS. 16 to 21A-21C illustrate various stages of an exemplary method for manufacturing a semiconductor structure according to the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

Various embodiments will be described more fully hereinafter with reference to accompanying drawings. The description and the drawings are provided for illustrative only, and not intended to result in a limitation. The similar elements are indicated by similar reference numerals. For clarity, the elements may not be drawn to scale. In addition, some elements and/or reference numerals may be omitted from some drawings. It is contemplated that the elements and features of one embodiment can be beneficially incorporated in another embodiment without further recitation.

An aspect of the disclosure relates to a semiconductor structure. The semiconductor structure comprises a 3D transformer structure. The 3D transformer structure comprises a plurality of conductive layers arranged in parallel. The conductive layers have U-shaped configurations. The conductive layers comprise at least one conductive layer forming a primary circuit of the 3D transformer structure and at least one conductive layer forming a secondary circuit of the 3D transformer structure, and the at least one conductive layer of the primary circuit and the at least one conductive layer of the secondary circuit is electrically isolated from each other.

A total number of the conductive layers can be equal to or larger than 3, such as 3, 4, 5, and so on. According to some embodiments, the primary circuit can comprise two or more of the conductive layers which are electrically coupled with each other. According to some embodiments, the secondary circuit can comprise two or more of the conductive layers which are electrically coupled with each other. The two or more of the conductive layers which are all belong to the primary circuit or all belong to the secondary circuit can be electrically coupled with each other through one or more conductive lines in a same layer and a plurality of vias connecting the one or more conductive lines and the two or more of the conductive layers. According to some embodiments, the 3D transformer structure can comprise two or more of the primary circuit. According to some embodiments, the 3D transformer structure can comprise two or more of the secondary circuit.

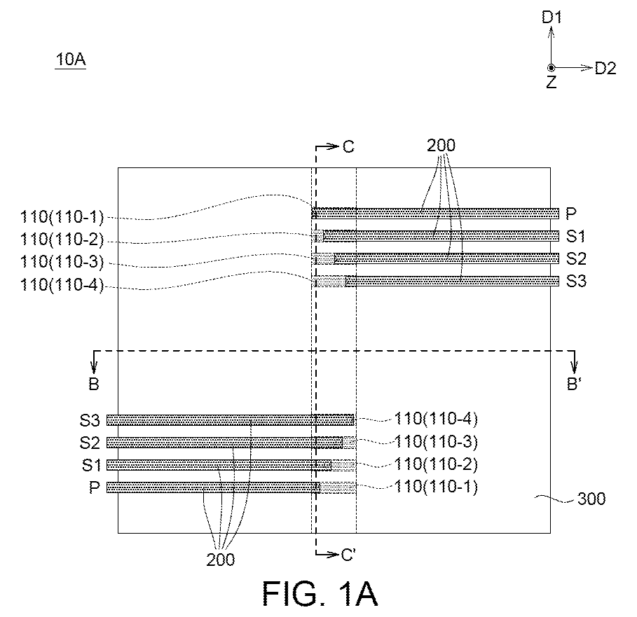

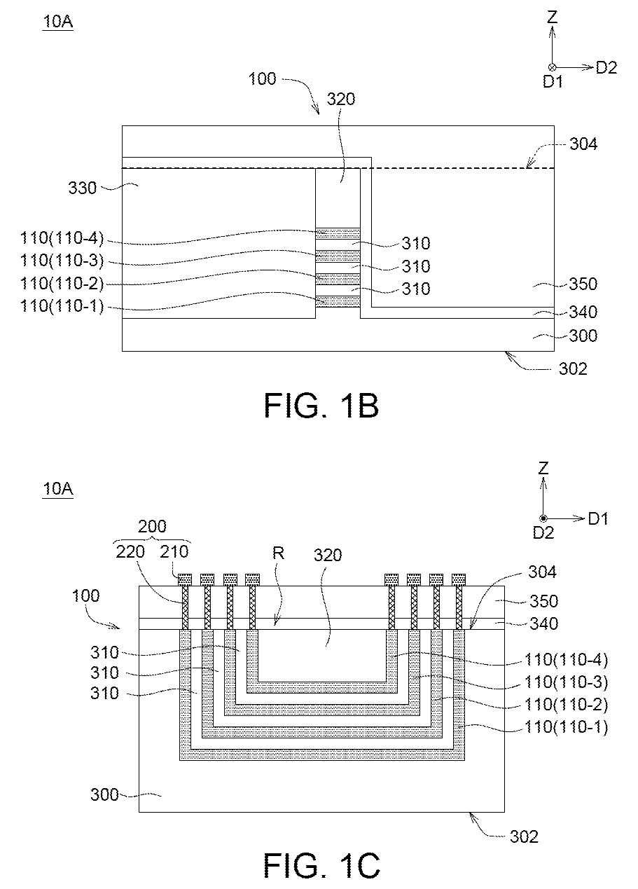

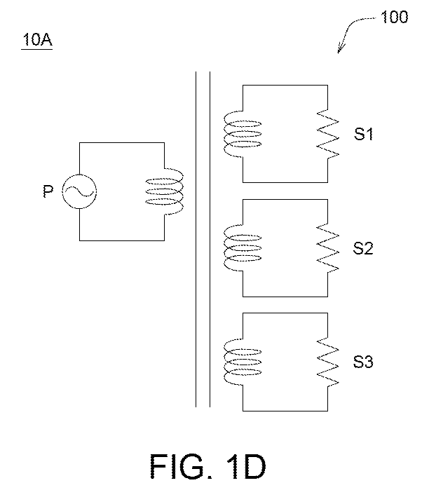

Referring to FIGS. 1A-1D, an exemplary semiconductor structure 10A according to the disclosure is shown, wherein FIG. 1A is a top view of the semiconductor structure 10A, FIG. 1B is a cross sectional view of the semiconductor structure 10A along line B-B’ in FIG. 1A, FIG. 1C is a cross sectional view of the semiconductor structure 10A along line C-C’ in FIG. 1A, and FIG. 1D shows a circuit of the 3D transformer structure 100 of the semiconductor structure 10A.

The semiconductor structure 10A comprises a 3D transformer structure 100, conductive components 200 for the 3D transformer structure 100, and a substrate 300. The semiconductor structure 10A has a first horizontal direction D1, a second horizontal direction D2 perpendicular to the first horizontal direction D1, and a vertical direction Z perpendicular to the first horizontal direction D1 and the second horizontal direction D2.

Specifically, the substrate 300 can be any suitable substrate used in the semiconductor field. The substrate 300 has a bottom surface 302 and a top surface 304. The first horizontal direction D1 and the second horizontal direction D2 can be defined as directions substantially parallel to the top surface 304, and the vertical direction Z can be defined as a normal direction of the top surface 304. In the semiconductor structure 10A, the substrate 300 has a recess R extending from the top surface 304 towards the bottom surface 302.

The 3D transformer structure 100 comprises a plurality of conductive layers 110. In the semiconductor structure 10A, the conductive layers 110 are disposed in the recess R. As such, the conductive layers 110 are disposed under the top surface 304 of the substrate 300. In the semiconductor structure 10A, the U-shaped configurations of the conductive layers 110 are vertical to the substrate 300, as shown in FIG. 1C.

The conductive layers 110 of the semiconductor structure 10A comprise a first conductive layer 110-1, a second conductive layer 110-2, a third conductive layer 110-3, and a fourth conductive layer 110-4 arranged in sequence. The first conductive layer 110-1 to the fourth conductive layer 110-4 are arranged in sequence in a direction from the bottom surface 302 of the substrate 300 to the top surface 304 of the substrate 300. More specifically, each U-shaped configuration of the conductive layers 110 can be constituted by two end portions and a central portion connecting the two end portions, wherein the end portions are parallel to each other, and the central portion is perpendicular to the end portions. The central portion of the first conductive layer 110-1 is closer to the bottom surface 302 of the substrate 300 than the central portion of the fourth conductive layer 110-4. With such an arrangement, a total length of the first conductive layer 110-1 is larger than a total length of the second conductive layer 110-2, the total length of the second conductive layer 110-2 is larger than a total length of the third conductive layer 110-3, and the total length of the third conductive layer 110-3 is larger than a total length of the fourth conductive layer 110-4.

In the semiconductor structure 10A, the first conductive layer 110-1 belongs to a primary circuit P, the second conductive layer 110-2 belongs to a secondary circuit S1, the third conductive layer 110-3 belongs to another secondary circuit S2, and the fourth conductive layer 110-4 belongs to still another secondary circuit S3, as indicated in FIG. 1A. In other words, the first conductive layer 110-1 to the fourth conductive layer 110-4 are electrically isolated from each other.

The semiconductor structure 10A can comprise a plurality of intervening dielectric layers 310 separating the conductive layers 110 from each other. Similarly, the intervening dielectric layers 310 have U-shaped configurations. The semiconductor structure 10A can further comprise a dielectric material 320 disposed in the recess R above the conductive layers 110 and the intervening dielectric layers 310. The semiconductor structure 10A can further comprise a dielectric material 330 for filling the recess R at a side of the conductive layers 110, the intervening dielectric layers 310, and the dielectric material 320. The semiconductor structure 10A can further comprise a dielectric layer 340 conformally extending from above the dielectric material 330 and the dielectric material 320, through sidewalls of the dielectric material 320, the conductive layers 110, and the intervening dielectric layers 310 at a side opposite to the dielectric material 330, to the bottom of the recess R. The semiconductor structure 10A can further comprise a dielectric material 350 disposed on the dielectric layer 340. The dielectric material 350 fills into a remaining space of the recess R.

The electrical connection for the conductive layers 110 can be achieved by the conductive components 200 arranged based on a circuit design. The conductive components 200 can comprise one or more conductive lines 210 and a plurality of vias 220. The one or more conductive lines 210 are disposed in a layer on the dielectric material 350. The vias 220 penetrate through the dielectric material 350 and the dielectric layer 340, and connect the one or more conductive lines 210 with the corresponding conductive layers 110.

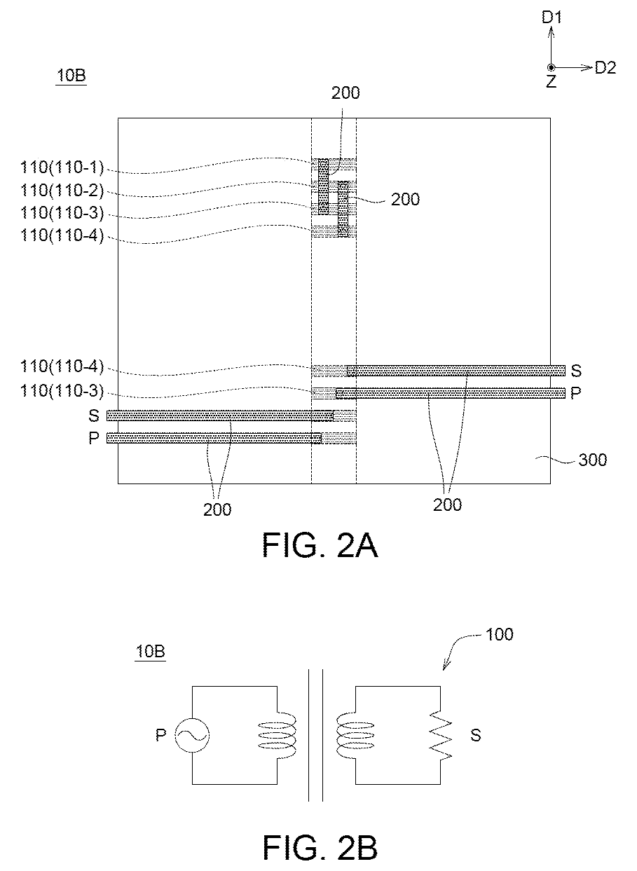

Referring to FIGS. 2A-2B, an exemplary semiconductor structure 10B according to the disclosure is shown, wherein FIG. 2A is a top view of the semiconductor structure 10B, and FIG. 2B shows a circuit of the 3D transformer structure 100 of the semiconductor structure 10B. The semiconductor structure 10B is arranged in a manner similar to the semiconductor structure 10A. The difference is that in the semiconductor structure 10B, the conductive components 200 are arranged in a different manner so as to connect the conductive layers 110 based on a different circuit design. In the semiconductor structure 10B, the first conductive layer 110-1 and the third conductive layer 110-3 belong to the primary circuit P and are electrically coupled with each other, and the second conductive layer 110-2 and the fourth conductive layer 110-4 belong to the secondary circuit S and are electrically coupled with each other. Other details of the semiconductor structure 10B are similar to those described above with respect to the semiconductor structure 10A, and thus are not repeated herein.

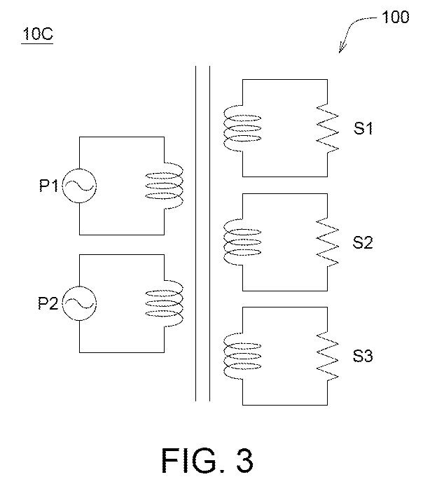

Referring to FIG. 3, an exemplary semiconductor structure 10C according to the disclosure is shown, wherein FIG. 3 shows a circuit of the 3D transformer structure 100 of the semiconductor structure 10C. The semiconductor structure 10C is arranged in a manner similar to the semiconductor structure 10A. The difference is that the semiconductor structure 10C can have five conductive layers 110 connected by the conductive components 200 in a suitable manner so as to achieve a circuit design as shown in FIG. 3. Other details of the semiconductor structure 10C are similar to those described above with respect to the semiconductor structure 10A, and thus are not repeated herein.

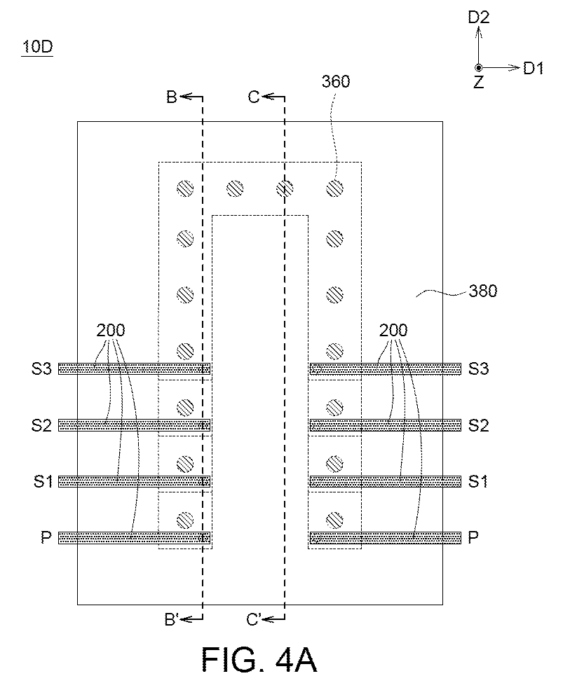

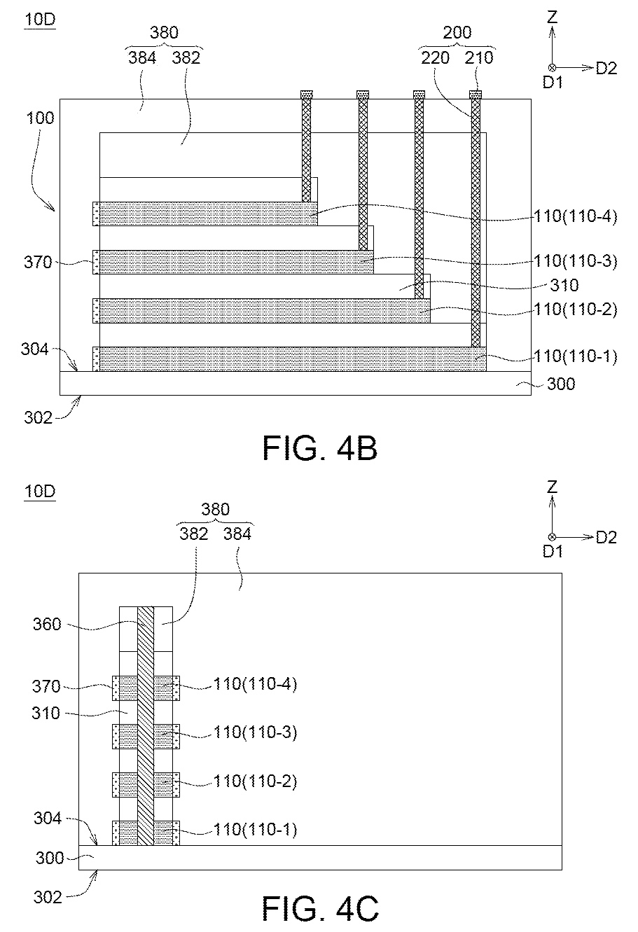

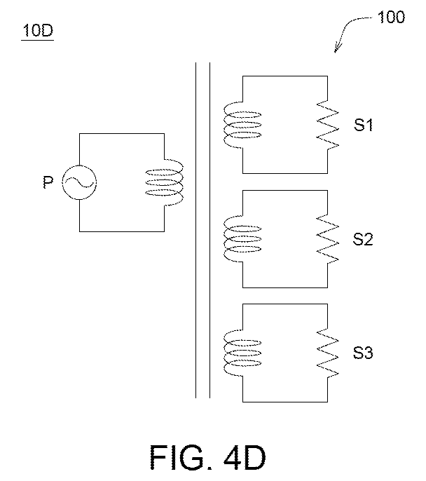

Referring to FIGS. 4A-4D, an exemplary semiconductor structure 10D according to the disclosure is shown, wherein FIG. 4A is a top view of the semiconductor structure 10D, FIG. 4B is a cross sectional view of the semiconductor structure 10D along line B-B’ in FIGS. 4A, 4C, is a cross sectional view of the semiconductor structure 10D along line C-C’ in FIGS. 4A, and 4D, shows a circuit of the 3D transformer structure 100 of the semiconductor structure 10D.

The conductive layers 110 of the semiconductor structure 10D are disposed on the substrate 300. More specifically, the conductive layers 110 and the intervening dielectric layers 310 can be stacked alternately on the substrate 300. As such, the conductive layers 110 are disposed above the top surface 304 of the substrate 300. The U-shaped configurations of the conductive layers 110 of the semiconductor structure 10D are parallel to the substrate 300. In some embodiments, up to hundreds of pairs of the conductive layer 110 and the intervening dielectric layer 310 can be stacked. The stack of the conductive layers 110 and the intervening dielectric layers 310 can have stair structures at the end portions of the U-shaped configurations. With such an arrangement, a total length of the first conductive layer 110-1 is larger than a total length of the second conductive layer 110-2, the total length of the second conductive layer 110-2 is larger than a total length of the third conductive layer 110-3, and the total length of the third conductive layer 110-3 is larger than a total length of the fourth conductive layer 110-4.

The semiconductor structure 10D can further comprise a plurality of supporting components 360 through the stack. The semiconductor structure 10D can further comprise a plurality of barrier layers 370 on sidewalls of the conductive layers 110, particularly on sidewalls of the central portions of the U-shaped configurations. The semiconductor structure 10D can further comprise a dielectric layer 380 on the stack.

The conductive components 200 can comprise one or more conductive lines 210 and a plurality of vias 220. The one or more conductive lines 210 are disposed in a layer on the dielectric layer 380. The vias 220 penetrate through the dielectric layer 380 and land on the corresponding conductive layers 110 at the stair structures, and connect the one or more conductive lines 210 with the corresponding conductive layers 110.

In the semiconductor structure 10D, the first conductive layer 110-1 belongs to a primary circuit P, the second conductive layer 110-2 belongs to a secondary circuit S1, the third conductive layer 110-3 belongs to another secondary circuit S2, and the fourth conductive layer 110-4 belongs to still another secondary circuit S3, as indicated in FIG. 4A. In other words, the first conductive layer 110-1 to the fourth conductive layer 110-4 are electrically isolated from each other.

Other details of the semiconductor structure 10D can be similar to those described above with respect to the semiconductor structure 10A, and thus are not repeated herein.

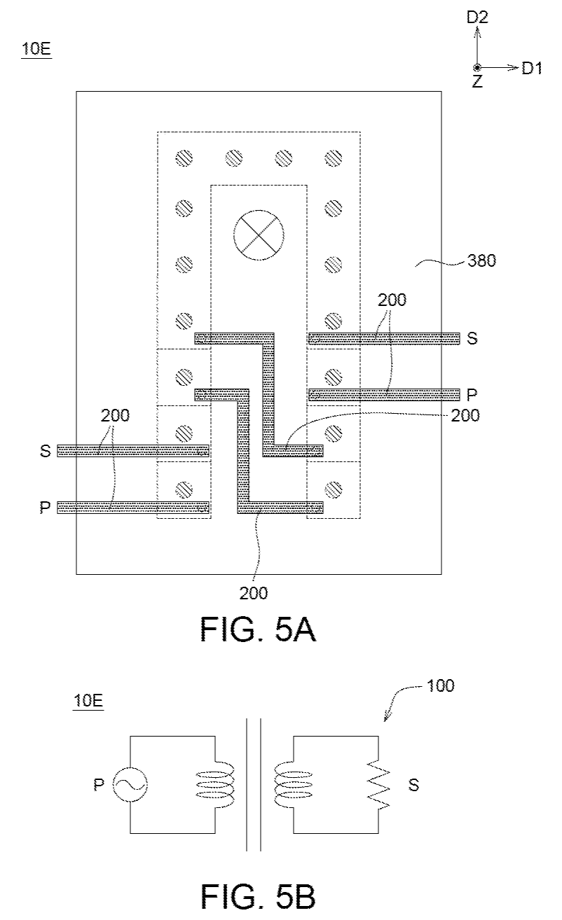

Referring to FIGS. 5A-5B, an exemplary semiconductor structure 10E according to the disclosure is shown, wherein FIG. 5A is a top view of the semiconductor structure 10E, and FIG. 5B shows a circuit of the 3D transformer structure 100 of the semiconductor structure 10E. The semiconductor structure 10E is arranged in a manner similar to the semiconductor structure 10D. The difference is that the semiconductor structure 10E, the conductive components 200 are arranged in a different manner so as to connect the conductive layers 110 based on a different circuit design. In the semiconductor structure 10E, the first conductive layer 110-1 and the third conductive layer 110-3 belong to the primary circuit P and are electrically coupled with each other, and the second conductive layer 110-2 and the fourth conductive layer 110-4 belong to the secondary circuit S and are electrically coupled with each other. Other details of the semiconductor structure 10E are similar to those described above with respect to the semiconductor structure 10D, and thus are not repeated herein.

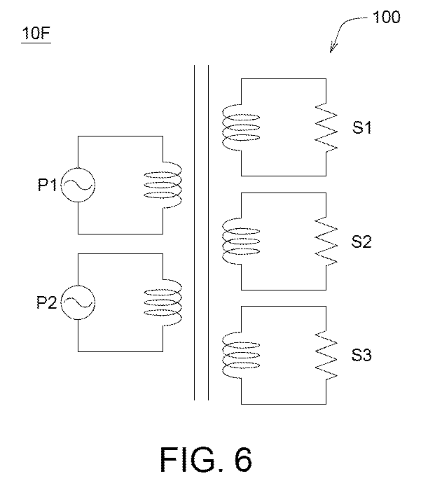

Referring to FIG. 6, an exemplary semiconductor structure 10F according to the disclosure is shown, wherein FIG. 6 shows a circuit of the 3D transformer structure 100 of the semiconductor structure 10F. The semiconductor structure 10F is arranged in a manner similar to the semiconductor structure 10D. The difference is that the semiconductor structure 10F can have five conductive layers 110 connected by the conductive components 200 in a suitable manner so as to achieve a circuit design as shown in FIG. 6. Other details of the semiconductor structure 10F are similar to those described above with respect to the semiconductor structure 10D, and thus are not repeated herein.

As illustrated above, in a semiconductor structure according to the disclosure, a “3D” transformer structure is provided by a plurality of U-shaped conductive layers. Compared to a conventional “2D” transformer structure, an area needed for a 3D transformer structure is significantly reduced. In addition, more conductive layers can be arranged in the transformer structure.

Further, in a semiconductor structure arranged like the semiconductor structures 10A to 10C, a magnetic field is in either the first horizontal direction D1 or the second horizontal direction D2, not a vertical direction Z. As such, the magnetic impact to the devices under the transformer structure, such as but not limited to bottom CMOS devices, can be further reduced or prevented.

In a semiconductor structure arranged like the semiconductor structures 10D to 10F, an inductance can be larger since a lot of conductive layers can be formed in the transformer structure. In addition, such a semiconductor structure can be manufactured using a self-aligned process, and thus the semiconductor structure can be manufactured precisely and easily.

Another aspect of the disclosure relates to a method for manufacturing a semiconductor structure according to the disclosure. The method comprises forming a 3D transformer structure. Forming the 3D transformer structure comprises forming a plurality of conductive layers arranged in parallel. The conductive layers have U-shaped configurations. The conductive layers comprise at least one conductive layer forming a primary circuit of the 3D transformer structure and at least one conductive layer forming a secondary circuit of the 3D transformer structure, and the at least one conductive layer of the primary circuit and the at least one conductive layer of the secondary circuit is electrically isolated from each other.

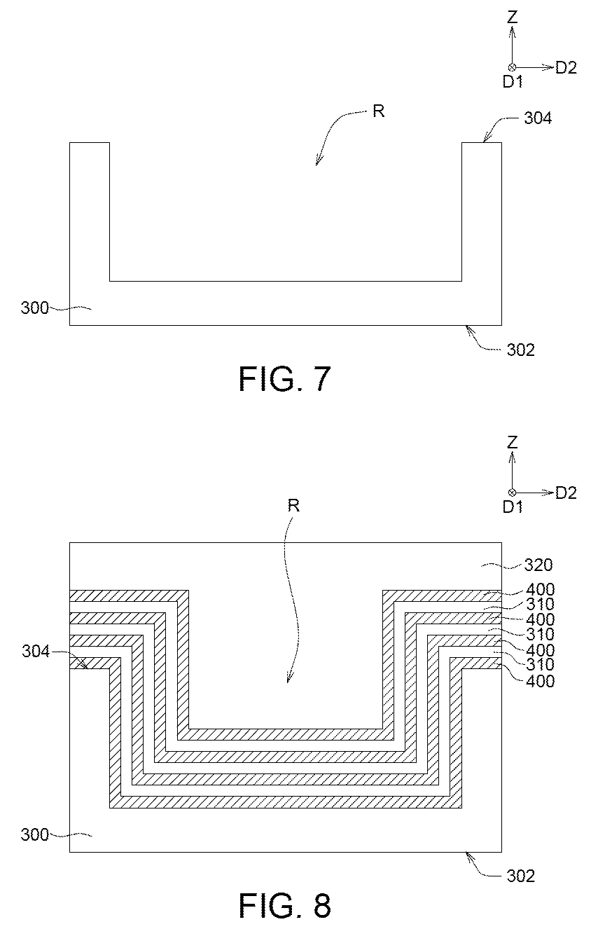

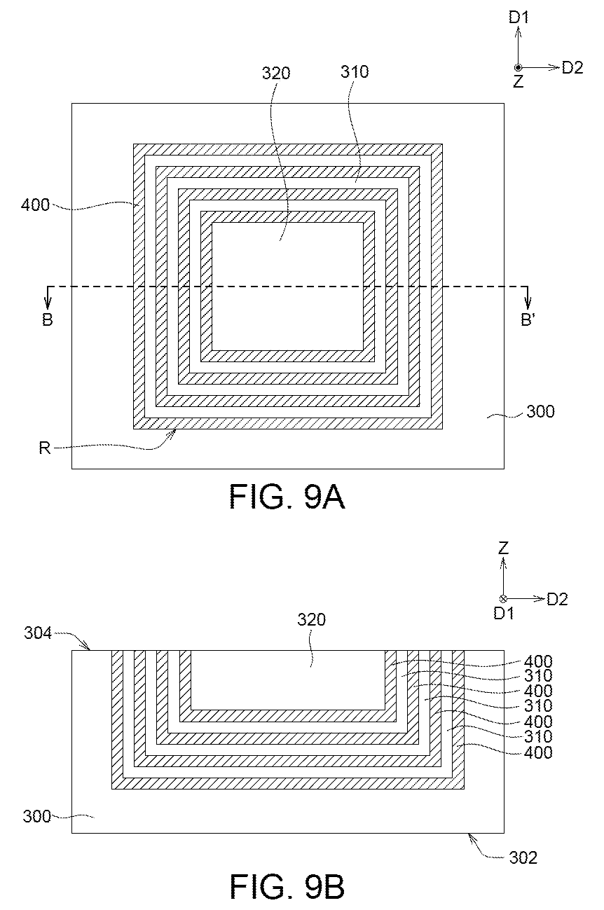

Referring to FIGS. 7 to 15A-15C, various stages of an exemplary method for manufacturing the semiconductor structure 10A are shown, wherein FIGS. 7 and 8 are cross sectional views, and for each stage illustrated in FIGS. 9A-9B to 15A-15C, the drawing indicated by “A” is a top view, the drawing indicated by “B” is a cross sectional view along lines B-B’ in the corresponding drawing “A” with the same drawing number, and the drawing “indicated by C” (if any) is a cross sectional view along line C-C’ in in the corresponding drawing “A” with the same drawing number.

As shown in FIG. 7, a substrate 300 is provided. Any suitable substrate can be used. The substrate 300 can comprise a dielectric layer (not shown), such as an oxide layer, at a top side. In other words, at least a portion of the top surface 304 of the substrate 300 is formed by the dielectric layer. A recess R is formed in the substrate 300. More specifically, the recess R can be formed in the dielectric layer. The recess R can be formed by a reactive ion etching (RIE) process, but not limited thereto.

As shown in FIG. 8, layers 400 of a sacrificial material and layers of an dielectric material (i.e., the intervening dielectric layers 310) are conformally formed alternately in the recess R. The sacrificial material can be nitride. The dielectric material can be oxide. According to some embodiments, each layer 400 can have a thickness equal to or larger than 1 um. Similarly, each intervening dielectric layer 310 can have a thickness equal to or larger than 1 um.

A dielectric material 320 is provided for filling a remaining space of the recess R. The dielectric material 320 can be oxide. Then, a planarization process, such as a CMP process, can be conducted and stopped at the top surface 304, as shown in FIGS. 9A-9B.

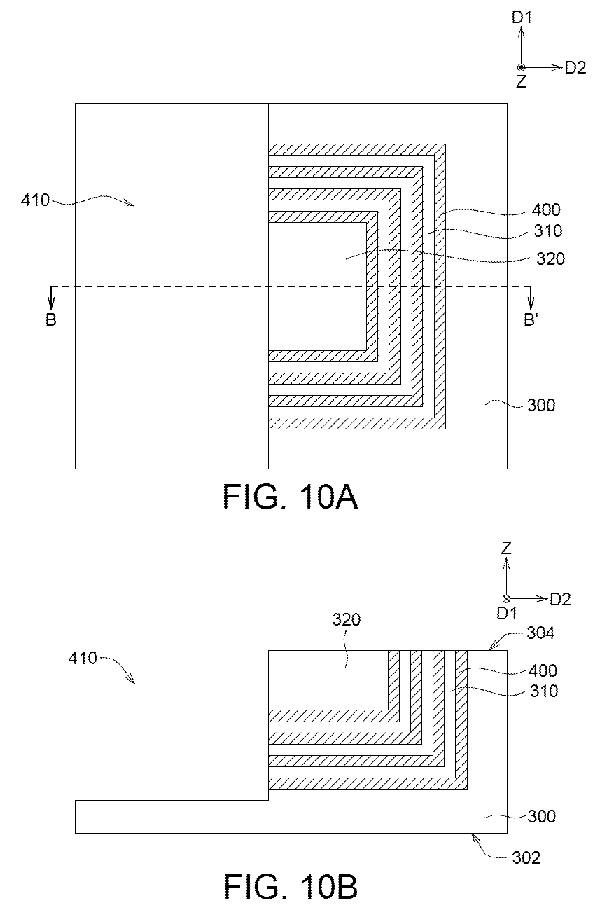

Thereafter, the layers 400 of the sacrificial material and the layers of the dielectric material (i.e., the intervening dielectric layers 310) are patterned to U-shaped configurations. Specifically, as shown in FIGS. 10A-10B, almost half of the materials in the recess R close to a side of the recess R (the left side in FIG. 10A) are removed, and a first opening 410 is formed. This can be achieved by a RIE process, but not limited thereto.

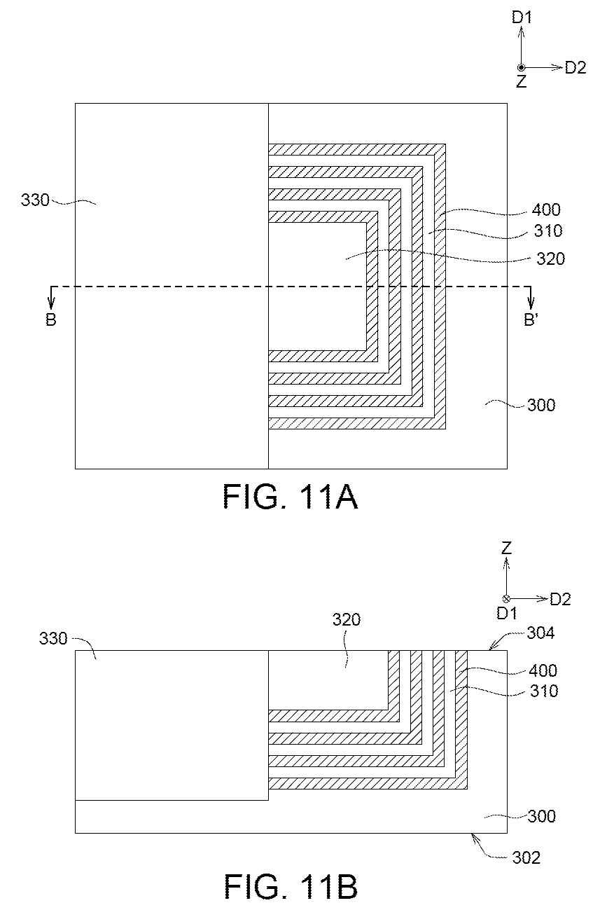

As shown in FIGS. 11A-11B, a dielectric material 330 is filled into the first opening 410. The dielectric material 330 can be oxide. A deposition process and an optional planarization process, such as a CMP process, can be conducted for the provision of the dielectric material 330.

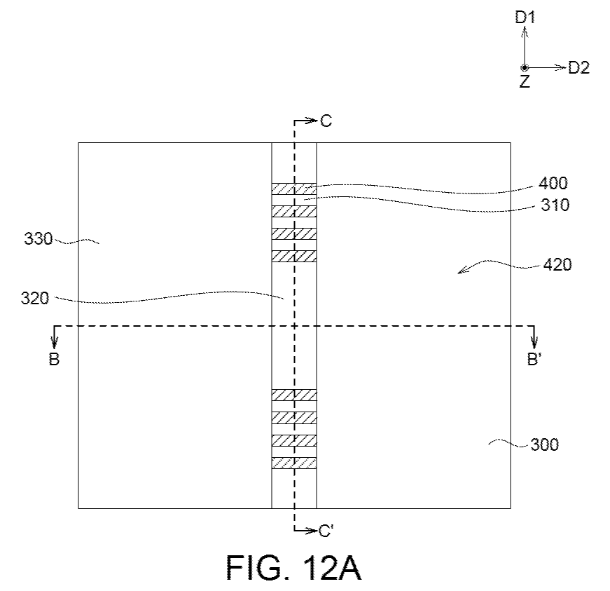

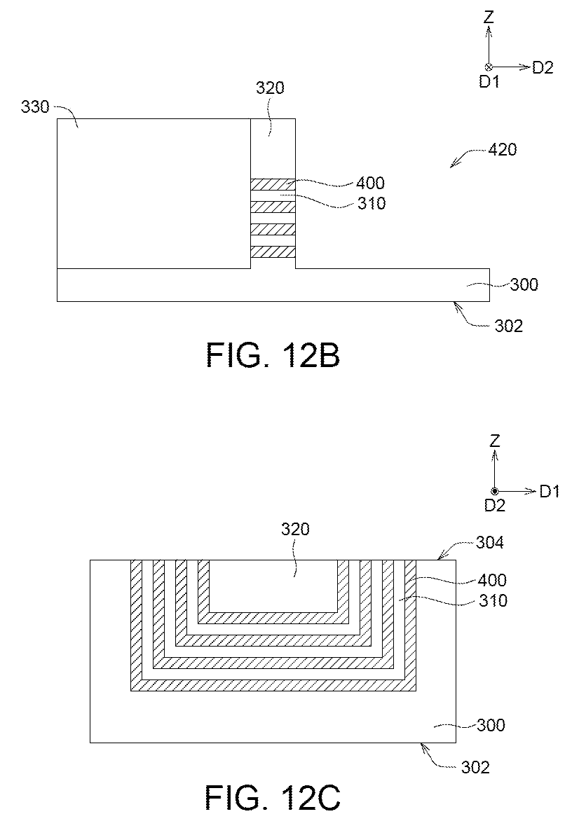

As shown in FIGS. 12A-12C, almost half of the materials in the recess R close to an opposite side of the recess R (the right side in FIG. 12A) are removed, and a second opening 420 is formed. This can be achieved by a RIE process, but not limited thereto.

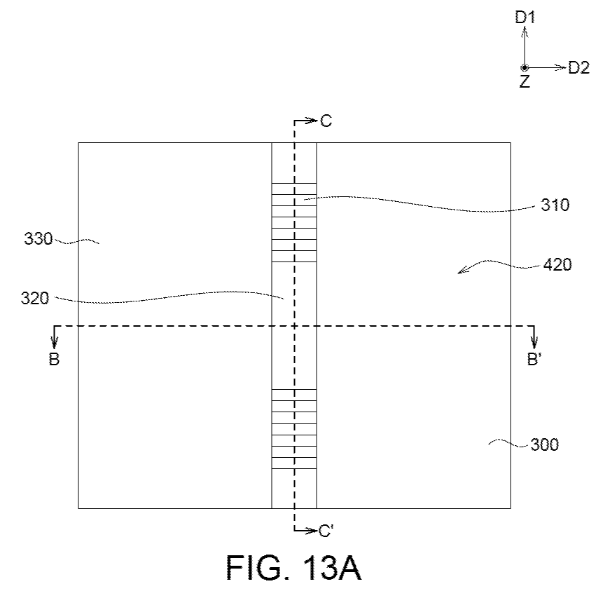

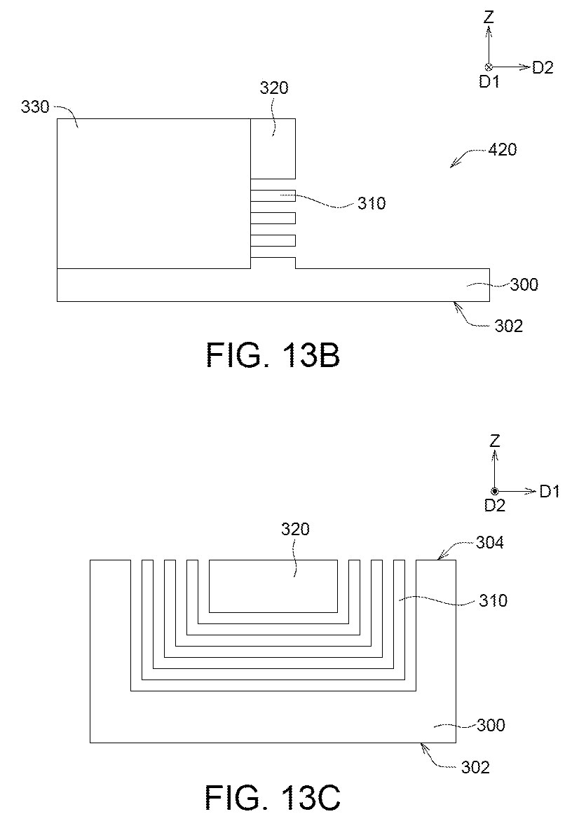

As shown in FIGS. 13A-13C, the sacrificial material is removed. The sacrificial material can be removed by a selective etching process using, for example, H₃PO₄ through the second opening 420, but not limited thereto.

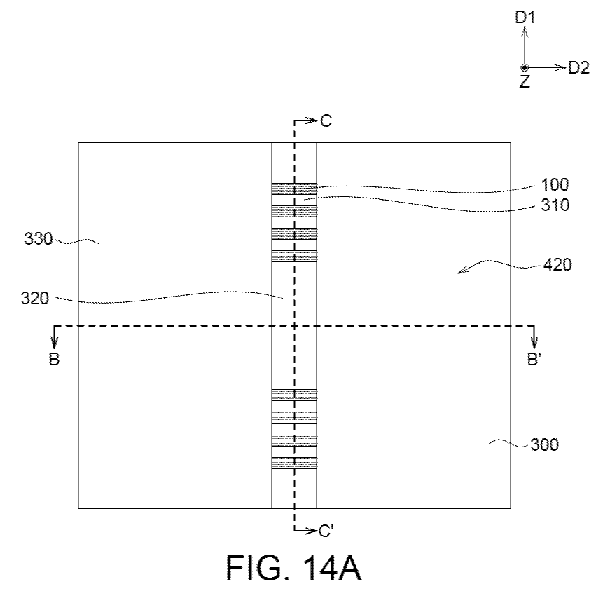

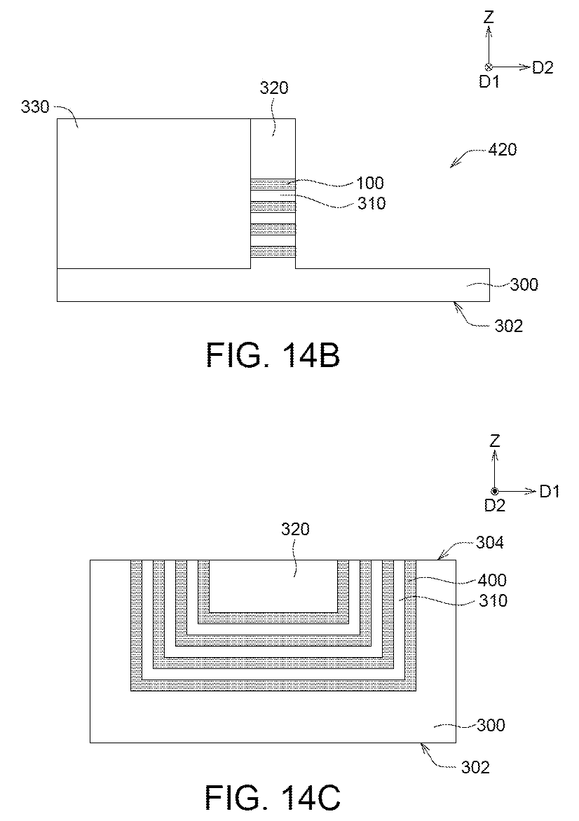

As shown in FIGS. 14A-14C, the conductive layers 110 are formed in spaces produced by removing the sacrificial material. According to some embodiments, the conductive layers 110 can comprise barrier layers and conductive bodies. For example, TaN films can be formed on tops and bottoms of the spaces as the barrier layers. Then, Cu can be deposited or platted (with Cu seed layers) to form the conductive bodies. An optional wet etching process can be conducted to remove a redundant portion of Cu in the second opening 420. However, the disclosure is not limited thereto. Since each layer 400 can have a thickness equal to or larger than 1 um, each conductive layer 110 can also have a thickness equal to or larger than 1 um. As such, the transformer resistance can be reduced.

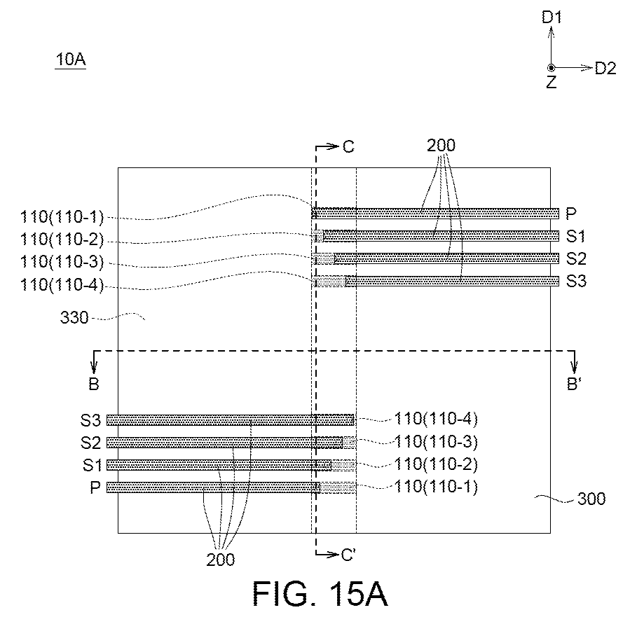

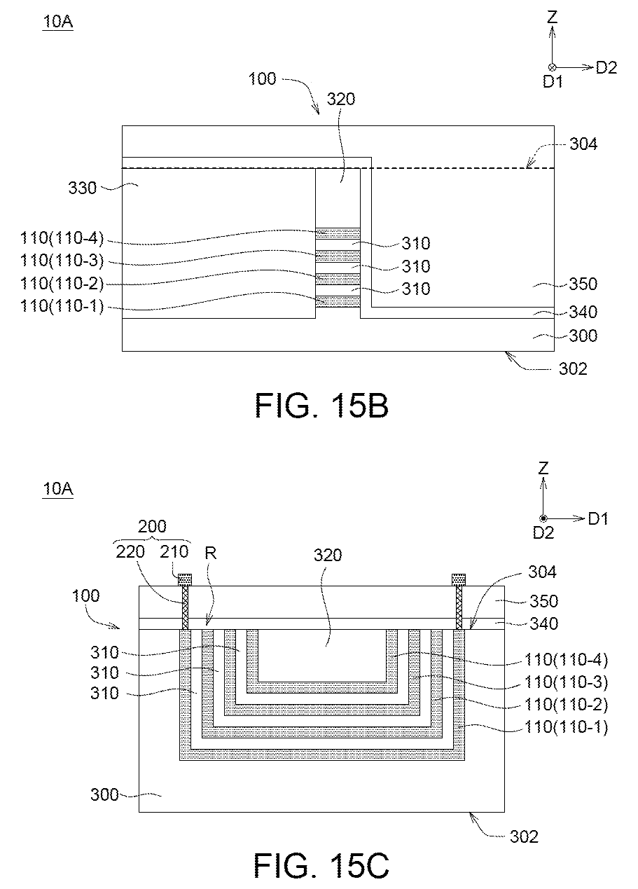

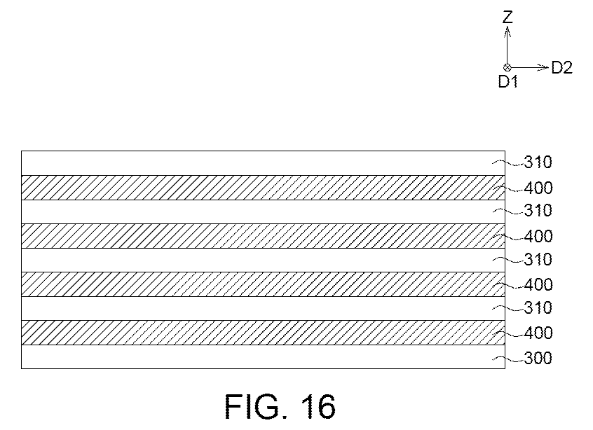

As shown in FIGS. 15A-15C, a dielectric layer 340 is conformally formed on the dielectric material 330 and the dielectric material 320, on sidewalls of the dielectric material 320, the conductive layers 110, and the intervening dielectric layers 310 exposed by the second opening 420, and on the bottom of the second opening 420. The dielectric layer 340 can be used as a barrier layer for preventing a diffusion of Cu from the conductive layers 110. A dielectric material 350 is formed on the dielectric layer 340. The dielectric material 350 fills into a remaining space of the second opening 420. Thereafter, a plurality of vias 220 and one or more conductive lines 210 can be formed for providing the electric connection for the conductive layers 110.

It is appreciated that the semiconductor structures 10B and 10C can be manufactured in a similar manner.

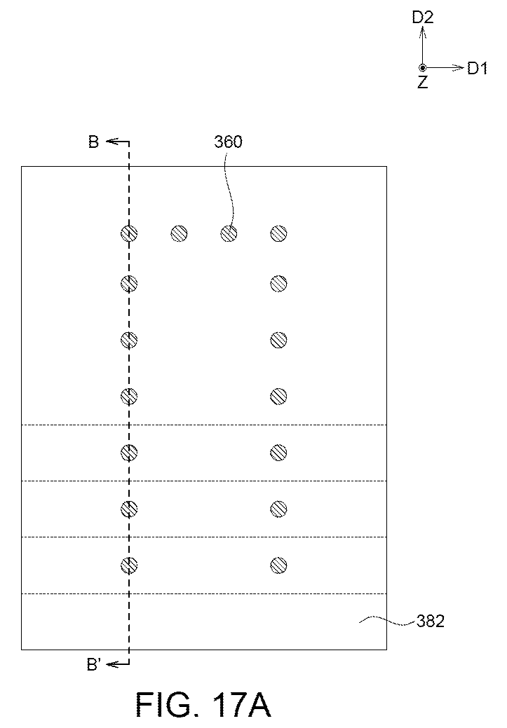

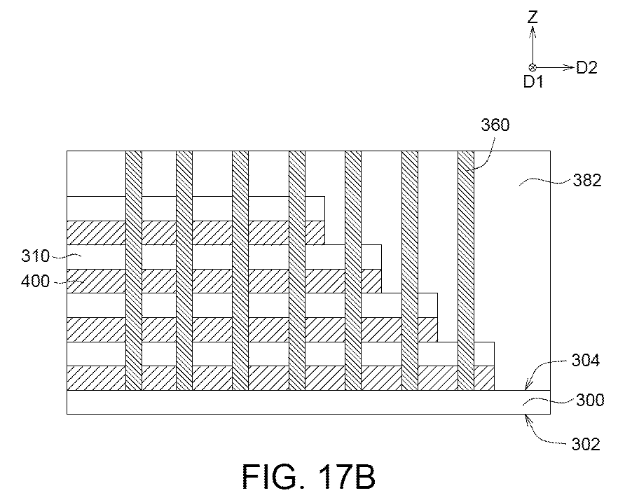

FIGS. 16 to 21A-21C illustrate various stages of an exemplary method for manufacturing the semiconductor structure 10D according to the disclosure, wherein FIG. 16 is a cross sectional view, and for each stage illustrated in FIGS. 17A-17B to 21A-21C, the drawing indicated by “A” is a top view, the drawing indicated by “B” is a cross sectional view along lines B-B’ in the corresponding drawing “A” with the same drawing number, and the drawing “indicated by C” (if any) is a cross sectional view along line C-C’ in in the corresponding drawing “A” with the same drawing number.

As shown in FIG. 16, a substrate 300 is provided. Layers 400 of a sacrificial material and layers of an dielectric material (i.e., the intervening dielectric layers 310) are formed alternately on the substrate 300, The sacrificial material can be nitride. The dielectric material can be oxide. According to some embodiments, each layer 400 can have a thickness equal to or larger than 1 um. Similarly, each intervening dielectric layer 310 can have a thickness equal to or larger than 1 um. According to some embodiments, up to hundreds of pairs of the layer 400 and the intervening dielectric layer 310 can be stacked.

As shown in FIGS. 17A-17B, a staircass process typically used in 3D memory manufacturing processes is conducted, such that the layers 400 of the sacrificial material and the layers of the dielectric material (i.e., the intervening dielectric layers 310) form a staircase structure on the substrate 300.

Then, a dielectric material 382 is formed covering the stack of the layers 400 of the sacrificial material and the intervening dielectric layers 310. The dielectric material 382 can be oxide. A plurality of supporting components 360 are formed through the dielectric material 382 and the stack for supporting the transformer pattern during subsequent processes to prevent collapse of the stack. The supporting components 360 can be formed by forming holes through the dielectric material 382 and the stack followed by filling a dielectric material, such as oxide, into the holes. However, the disclosure is not limited thereto.

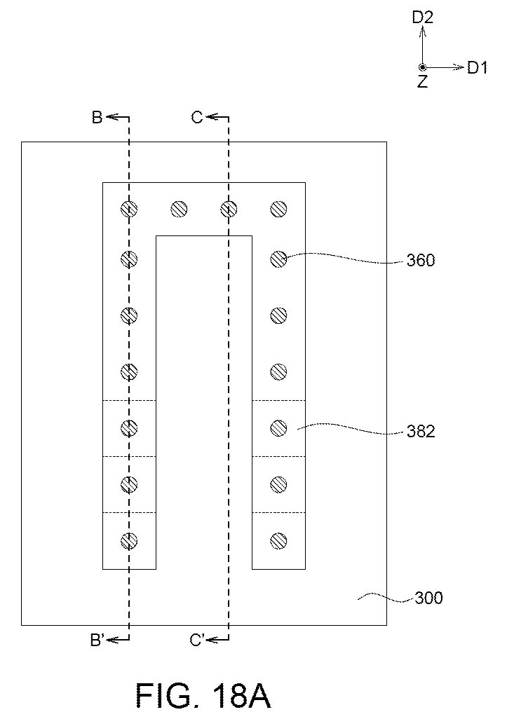

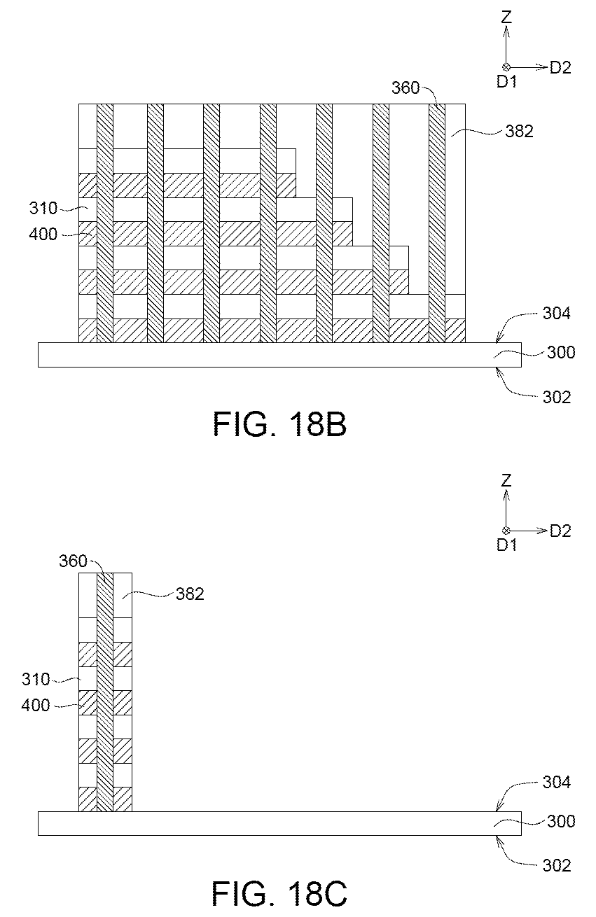

As shown in FIGS. 18A-18C, the layers 400 of the sacrificial material and the layers of the dielectric material (i.e., the intervening dielectric layers 310) are patterned to U-shaped configurations. The staircase structure constitutes end portions of the U-shaped configurations.

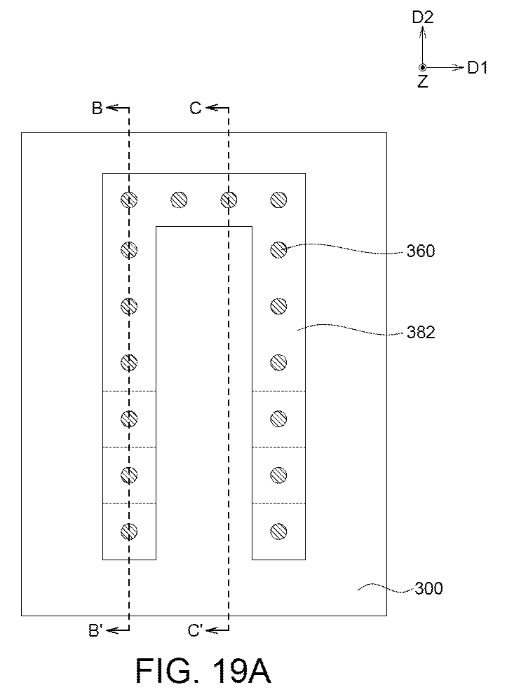

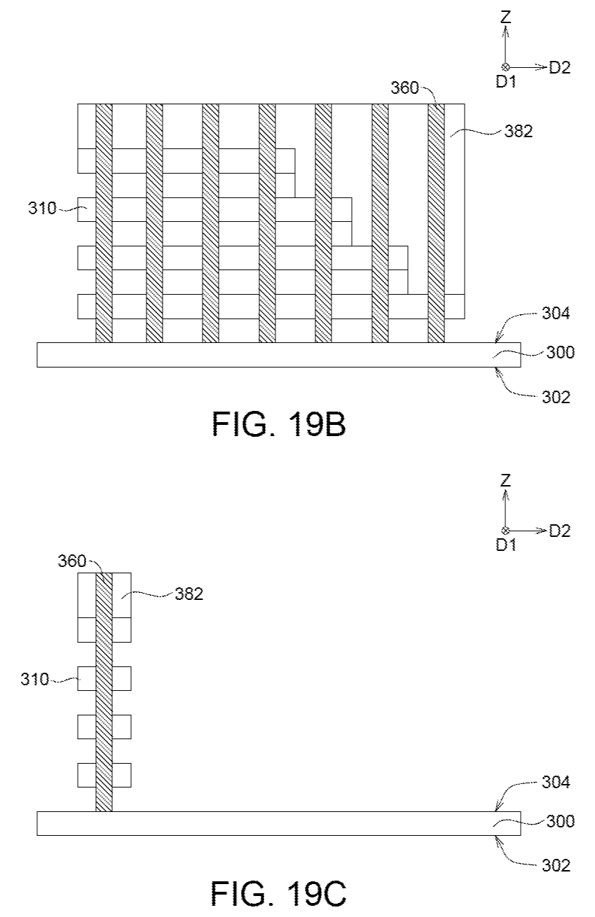

As shown in FIGS. 19A-19C, the sacrificial material is removed. The sacrificial material can be removed by a selective etching process using, for example, H₃PO₄ through the second opening 420, but not limited thereto.

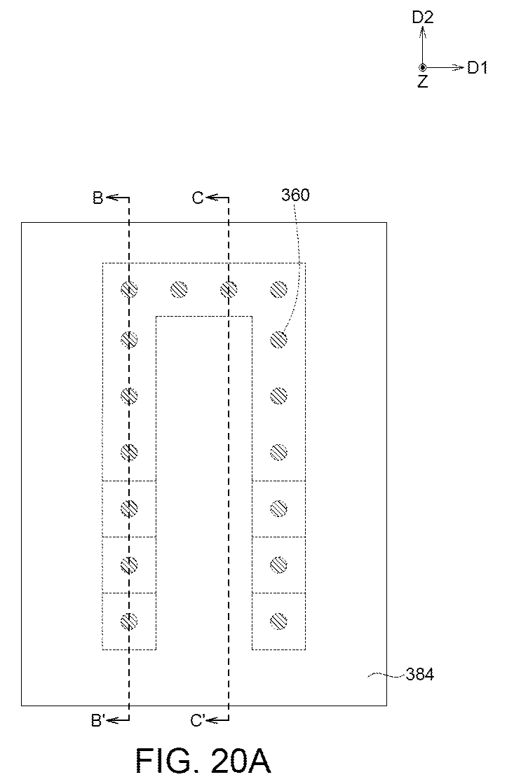

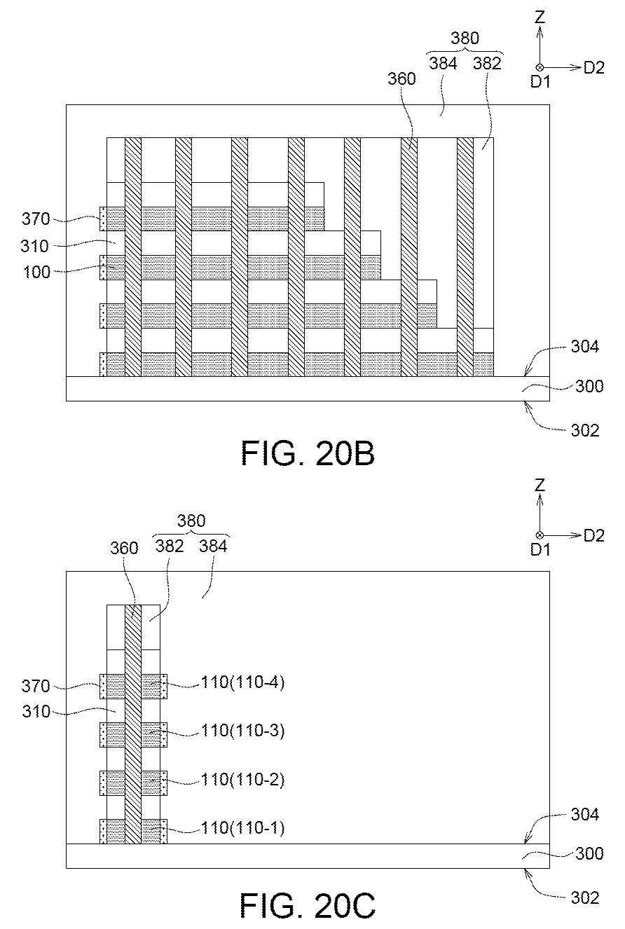

As shown in FIGS. 20A-20C, the conductive layers 110 are formed in spaces produced by removing the sacrificial material. According to some embodiments, the conductive layers 110 can comprise barrier layers and conductive bodies. For example, TaN films can be formed on tops and bottoms of the spaces as the barrier layers. Then, Cu can be deposited or platted (with Cu seed layers) to form the conductive bodies. An optional wet etching process can be conducted to remove a redundant portion of Cu. However, the disclosure is not limited thereto. Since each layer 400 can have a thickness equal to or larger than 1 um, each conductive layer 110 can also have a thickness equal to or larger than 1 um. As such, the transformer resistance can be reduced.

Optionally, a plurality of barrier layers 370 can be formed on sidewalls of the conductive layers 110, particularly on sidewalls of the central portions of the U-shaped configurations. The barrier layers 370 can be formed by depositing Co, TaN, TiN, or any other suitable material. The barrier layers 370 can prevent leakage of Cu.

Thereafter, a dielectric material 384 is formed covering the structure. The dielectric material 384 together with the dielectric material 382 constitute the dielectric layer 380.

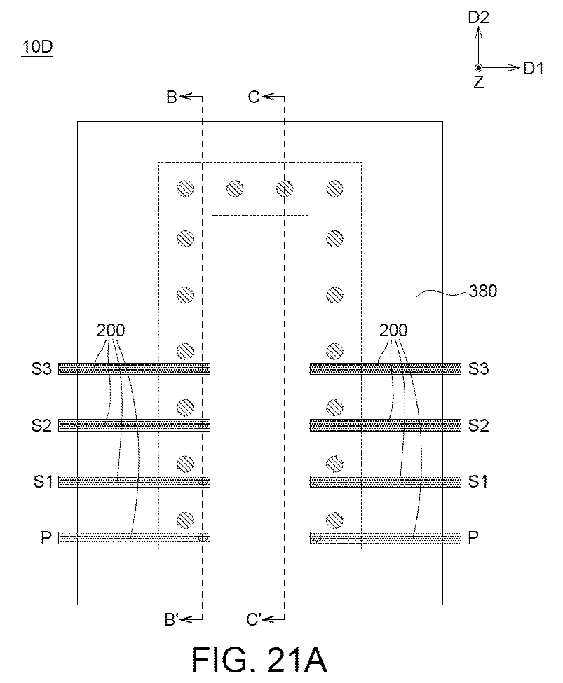

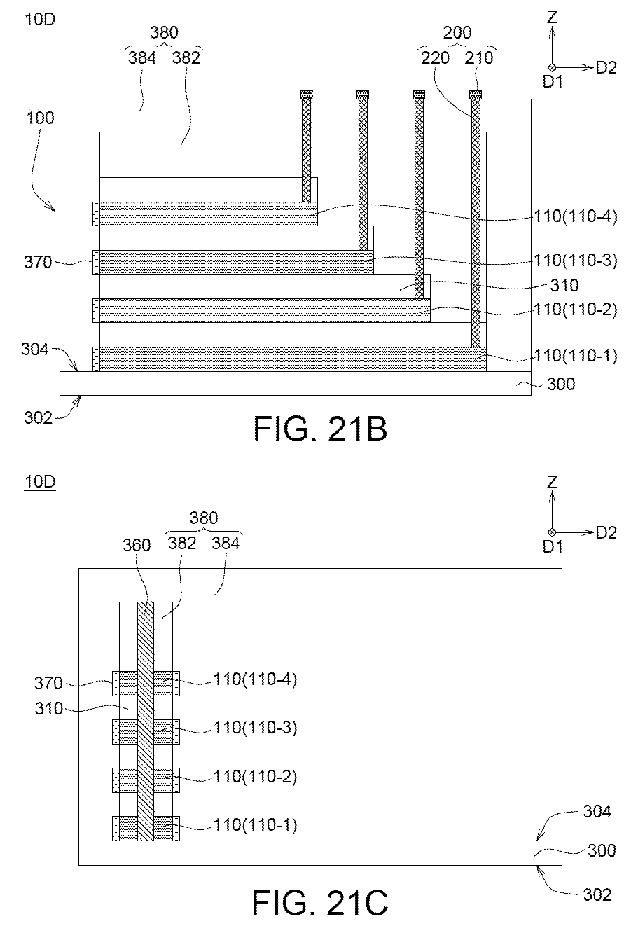

As shown in FIGS. 21A-21C, a plurality of vias 220 and one or more conductive lines 210 can be formed for providing the electric connection for the conductive layers 110.

It is appreciated that the semiconductor structures 10E and 10F can be manufactured in a similar manner.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A semiconductor structure, comprising:
a 3D transformer structure, comprising:
a plurality of conductive layers arranged in parallel, the conductive layers having U-shaped configurations;
wherein the conductive layers comprise at least one conductive layer forming a primary circuit of the 3D transformer structure and at least one conductive layer forming a secondary circuit of the 3D transformer structure, and the at least one conductive layer of the primary circuit and the at least one conductive layer of the secondary circuit is electrically isolated from each other.

2. The semiconductor structure according to claim 1, wherein a total number of the conductive layers is equal to or larger than 3.

3. The semiconductor structure according to claim 1, wherein the primary circuit comprises two or more of the conductive layers which are electrically coupled with each other.

4. The semiconductor structure according to claim 1, wherein the secondary circuit comprises two or more of the conductive layers which are electrically coupled with each other.

5. The semiconductor structure according to claim 1, wherein two or more of the conductive layers which are all belong to the primary circuit or all belong to the secondary circuit are electrically coupled with each other through one or more conductive lines in a same layer and a plurality of vias connecting the one or more conductive lines and the two or more of the conductive layers.

6. The semiconductor structure according to claim 1, wherein the 3D transformer structure comprises two or more of the primary circuit.

7. The semiconductor structure according to claim 1, wherein the 3D transformer structure comprises two or more of the secondary circuit.

8. The semiconductor structure according to claim 1, wherein the conductive layers comprise a first conductive layer, a second conductive layer, a third conductive layer, and a fourth conductive layer arranged in sequence.

9. The semiconductor structure according to claim 8, wherein a total length of the first conductive layer is larger than a total length of the second conductive layer, the total length of the second conductive layer is larger than a total length of the third conductive layer, and the total length of the third conductive layer is larger than a total length of the fourth conductive layer.

10. The semiconductor structure according to claim 8, wherein the first conductive layer belongs to the primary circuit, the second conductive layer belongs to the secondary circuit, the third conductive layer belongs to another secondary circuit, and the fourth conductive layer belongs to still another secondary circuit.

11. The semiconductor structure according to claim 8, wherein the first conductive layer and the third conductive layer belong to the primary circuit and are electrically coupled with each other, and the second conductive layer and the fourth conductive layer belong to the secondary circuit and are electrically coupled with each other.

12. The semiconductor structure according to claim 8, further comprising:
a substrate;
wherein the first conductive layer to the fourth conductive layer are arranged in sequence in a direction from a bottom surface of the substrate to a top surface of the substrate.

13. The semiconductor structure according to claim 12, wherein the U-shaped configurations of the conductive layers are vertical to the substrate.

14. The semiconductor structure according to claim 13, wherein the conductive layers are disposed under the top surface of the substrate.

15. The semiconductor structure according to claim 12, wherein the U-shaped configurations of the conductive layers are parallel to the substrate.

16. The semiconductor structure according to claim 15, wherein the conductive layers are disposed above the top surface of the substrate.

17. The semiconductor structure according to claim 1, further comprising:
a plurality of intervening dielectric layers separating the conductive layers from each other, the intervening dielectric layers having U-shaped configurations.

18. A method for manufacturing a semiconductor structure, comprising:
forming a 3D transformer structure, comprising:
forming a plurality of conductive layers arranged in parallel, the conductive layers having U-shaped configurations;
wherein the conductive layers comprise at least one conductive layer forming a primary circuit of the 3D transformer structure and at least one conductive layer forming a secondary circuit of the 3D transformer structure, and the at least one conductive layer of the primary circuit and the at least one conductive layer of the secondary circuit is electrically isolated from each other.

19. The method according to claim 18, comprising:
providing a substrate;
forming a recess in the substrate;
conformally forming layers of a sacrificial material and layers of an dielectric material alternately in the recess;
patterning the layers of the sacrificial material and the layers of the dielectric material to U-shaped configurations;
removing the sacrificial material; and
forming the conductive layers in spaces produced by removing the sacrificial material.

20. The method according to claim 18, comprising:
providing a substrate;
forming layers of a sacrificial material and layers of an dielectric material alternately on the substrate, wherein the layers of the sacrificial material and the layers of the dielectric material form a staircase structure on the substrate;
patterning the layers of the sacrificial material and the layers of the dielectric material to U-shaped configurations, wherein the staircase structure constitutes end portions of the U-shaped configurations;
removing the sacrificial material; and
forming the conductive layers in spaces produced by removing the sacrificial material.
